(19) United States
(12) Patent Application Publication
(10) Pub. No.: US 2017/0285116 A1
(43) Pub. Date: Oct. 5, 2017

(54) MAGNETIC SENSOR

(71) Applicant: Johnson Electric S.A., Murten (CH)

(72) Inventors: Hui Min GUO, Hong Kong (CN); Shu Zuo LOU, Hong Kong (CN); Xiao Ming CHEN, Hong Kong (CN); Guang Jie CAI, Hong Kong (CN); Chun Fai WONG, Hong Kong (CN); Xiao HUO, Hong Kong (CN)

(21) Appl. No.: 15/475,910

(22) Filed: Mar. 31, 2017

(30) Foreign Application Priority Data
Apr. 1, 2016 (CN) 2016 1020 3297.0

(51) Int. Cl. G01R 33/07

(52) U.S. Cl. CPC G01R 33/07

(57) ABSTRACT

A magnetic sensor disclosed according to the present application is provided, which includes at least two magnetic sensing elements forming at least one magnetic sensing element pair, and currents in the magnetic sensing elements in each of the at least one magnetic sensing element pair are reverse and the magnetic sensing elements are arranged symmetrically.

### CROSS REFERENCE TO RELATED APPLICATIONS

This non-provisional patent application claims priority under 35 U.S.C. §119(a) from Patent Application No. CN201610203297.0 filed in the People's Republic of China on Apr. 1, 2016.

### TECHNICAL FIELD

The present disclosure relates to a semiconductor element, and more particularly to a magnetic sensor.

### BACKGROUND

A Hall element is a magnetic sensing element, which is generally used in a motor to detect a rotor speed, and further to detect a location of a magnetic pole. Under an effect of a magnetic field force, Hall effect may be produced in a metal or a powered semiconductor, and an output voltage is directly proportional to a magnetic field intensity. Hall effect means a physical phenomenon that a transverse electrical potential difference is produced when a magnetic field acts on a carrying metal conductor or on current carriers in a semiconductor, and the nature of the Hall effect is that when current carriers in a solid material move under an externally applied magnetic field, motion trajectory of the current carriers is deviated since the current carriers are subjected to Lorentz force, and electric charges are accumulated at two sides of the material, thus producing an electric field perpendicular to the current direction, and finally balancing a Lorentz force and a repulsive force of the electric field subjected by the current carriers, thereby establishing a stable electric potential difference which is a Hall voltage, between the two sides.

A magnetic sensor in a motor includes only one magnetic sensing element, and a single magnetic sensing element has a fixed angular separation. Due to the process deviation of the single asymmetric magnetic sensing element of the magnetic sensor, for example, the differences of doping concentration and photolithography, the magnetic sensor has an asymmetric electric resistance, thus causing an inaccurate magnetic field intensity sensed by the magnetic sensing element.

### SUMMARY

A magnetic sensor is provided according to the present application, which eliminates asymmetry of electric resistance of a single magnetic sensing element of a conventional magnetic sensor due to process deviation by at least two magnetic sensing elements symmetrically arranged.

To achieve the above object, the following technical solutions are provided according to the present application.

A magnetic sensor includes at least two magnetic sensing elements. The at least two magnetic sensing elements form at least one magnetic sensing element pair, in which currents in the magnetic sensing elements in each of the at least one magnetic sensing element pair are reverse and the magnetic sensing elements are arranged symmetrically.

Preferably, each of the magnetic sensing elements comprises four contact terminals; and the contact terminals of each of the magnetic sensing elements are in connection with corresponding contact terminal buses respectively to form bus contact terminals.

Preferably, each of the magnetic sensing elements is in a cross shape, and the four contact terminals are respectively arranged at four endpoints of the magnetic sensing element.

Preferably, the contact terminals of each of the magnetic sensing elements are connected to the corresponding contact terminal buses via connecting lines having a same length.

Preferably, the magnetic sensing elements in the magnetic sensing element pair have the same geometrical shape.

Preferably, the magnetic sensing elements in different magnetic sensing element pairs have different geometrical shapes.

Preferably, the geometrical arrangement of multiple magnetic sensing element pairs is of a square shape, a diamond shape or a circular shape.

Preferably, the magnetic sensor includes four magnetic sensing elements arranged in a square semiconductor substrate. The magnetic sensing elements located at four diagonal positions of the square semiconductor substrate, and two diagonal magnetic sensing elements foam a magnetic sensing element pair.

Preferably, the two magnetic sensing elements arranged at diagonal positions are obliquely arranged at a same angle.

Preferably, the at least one magnetic sensing elements are located on edges of a circle.

A magnetic sensor includes at least one magnetic sensing element pair, and each of the at least one magnetic sensing element pair comprising two magnetic sensing elements; wherein currents in the two magnetic sensing element in each of the at least one magnetic sensing element pair are reverse and the two magnetic sensing elements are arranged symmetrically.

Preferably, each of the two magnetic sensing elements comprises four contact terminals; and the contact terminals of each of the two magnetic sensing elements are in connection with corresponding contact terminal buses respectively to form bus contact terminals.

Preferably, each of the two magnetic sensing elements is in a cross shape, and the four contact terminals are respectively arranged at four endpoints of the magnetic sensing element.

Preferably, the contact terminals of each of the two magnetic sensing elements are connected to the corresponding contact terminal buses via connecting lines having a same length.

Preferably, the two magnetic sensing elements in the magnetic sensing element pair have a same geometrical shape.

Preferably, the two magnetic sensing elements in different magnetic sensing element pairs have different geometrical shapes.

Preferably, the geometrical arrangement of the at least one magnetic sensing element pair is in a square shape, a diamond shape or a circular shape.

Preferably, the magnetic sensor further includes four magnetic sensing elements arranged in a square semiconductor substrate; wherein the magnetic sensing elements located at four diagonal positions of the square semiconductor substrate, and two diagonal magnetic sensing elements form a magnetic sensing element pair.

Preferably, the two magnetic sensing elements arranged at diagonal positions are obliquely arranged at a same angle.

Preferably, the at least one magnetic sensing elements are located on edges of a circle.

According to the above technical solutions, compared with the conventional technology, a magnetic sensor is provided according to the present application, which includes multiple magnetic sensing elements forming at least one magnetic sensing element pair, and currents in the magnetic sensing elements in each of the at least one magnetic sensing element pair are reverse and the magnetic sensing elements are arranged symmetrically. By the symmetrical arrangement and reverse currents of the magnetic sensing elements in the multiple magnetic sensing element pairs, the magnetic sensor according to the present disclosure can eliminate asymmetry of electric resistance of a single magnetic sensing element of a conventional magnetic sensor due to process deviation, and enable the magnetic sensing elements to sense the magnetic field intensity more accurately.

### BRIEF DESCRIPTION OF THE DRAWINGS

FIG. 1 is a schematic view of a magnetic sensing element according to one embodiment.

FIG. 2 is a schematic view of a magnetic sensor provided according to one embodiment.

FIG. 3 is a schematic view of a magnetic sensor according to another embodiment.

FIGS. 4 to 6 are schematic views of a geometrical layout of a magnetic sensor according to another alternative embodiments.

FIGS. 7 to 8 are schematic views of a geometrical layout of a magnetic sensor according to another alternative embodiments.

### DETAILED DESCRIPTION

The technical solutions of the embodiments of the present disclosure will be clearly and completely described as follows with reference to the accompanying drawings. Apparently, the embodiments as described below are merely part of, rather than all, embodiments of the present disclosure. Based on the embodiments of the present disclosure, any other embodiment obtained by a person skilled in the art without paying any creative effort shall fall within the protection scope of the present disclosure.

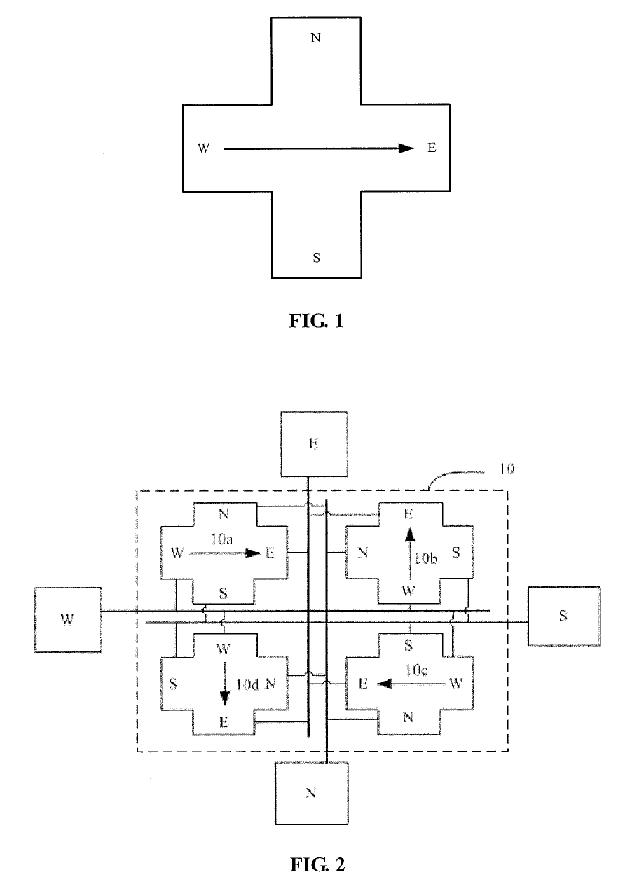

FIG. 1 shows a schematic view of a magnetic sensing element. The magnetic sensing element is provided with four contact terminals N, S, W, E, and a current of the magnetic sensing element flows from the contact terminal W to the contact terminal E. In other embodiments, the current of the magnetic sensing element may flow from the contact terminal E to the contact terminal W, or from the contact terminal N to the contact terminal S, or from the contact terminal S to the contact terminal N.

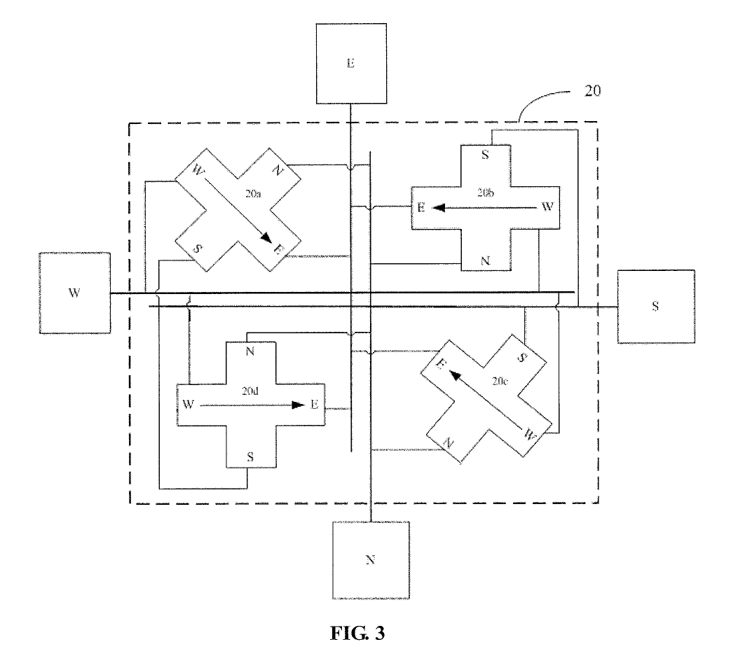

FIG. 2 shows a schematic view of a magnetic sensor 10 according to one embodiment. The magnetic sensor 10 is provided according to the present disclosure, which includes multiple magnetic sensing elements 10a, 10b, 10c, and 10d. The multiple magnetic sensing elements 10a, 10b, 10c, and 10d are respectively arranged at four diagonal positions of a square semiconductor substrate, and are arranged in a square shape, as shown in FIG. 2. In the embodiment, a current of each of the magnetic sensing elements 10a, 10b, 10c, and 10d flows from the contact terminal W to the contact terminal E, and a reverse direction of the current of each of the magnetic sensing elements may be achieved just by converting the positions of the contact terminals of the magnetic sensing element. In the embodiment, the square semiconductor substrate is a P-type substrate. In the embodiment, the magnetic sensor 10 is a Hall sensor, and the sensing elements may be not limited to Hall elements.

The magnetic sensing elements 10a, 10b, 10c, and 10d form two magnetic sensing element pairs, in which currents in the magnetic sensing elements in each of the at least one magnetic sensing element pair are reverse and the magnetic sensing elements are arranged symmetrically. In the embodiment, the magnetic sensing elements 10a and 10c arranged diagonally form one magnetic sensing element pair, and the magnetic sensing elements 10b and 10d arranged diagonally form the other magnetic sensing element pair. In other embodiments, the magnetic sensing elements 10a and 10b can form one magnetic sensing element pair, and the magnetic sensing elements 10c and 10d can form the other magnetic sensing element pair. Each of the multiple magnetic sensing elements includes four contact terminals. For each of the magnetic sensing elements, the contact terminals of the magnetic sensing element are connected with corresponding contact terminal buses respectively, thereby forming bus contact terminals W, E, S and N. In the embodiment, each of the multiple magnetic sensing elements is in a cross shape, and the four contact terminals are respectively arranged at four endpoints of the magnetic sensing element.

Preferably, the contract terminals of the magnetic sensing element are connected to the corresponding contact terminal buses via connecting lines having a same length.

One or more pairs of the multiple magnetic sensing elements are provided. The multiple magnetic sensing element pairs may be provided as one pair, two pairs, three pairs, and four pairs, etc. In those cases, specifically, the magnetic sensing elements may be arranged according to the same arrangement as shown in FIG. 2 as long as the magnetic sensing elements in each of the at least one magnetic sensing element pair are arranged symmetrically and currents in the magnetic sensing elements are reverse.

A magnetic sensor is provided according to the present disclosure, which includes multiple magnetic sensing elements which form at least one magnetic sensing element pair, in which currents in the magnetic sensing elements in each of the at least one magnetic sensing element pair are reverse and the magnetic sensing elements are arranged symmetrically. By the symmetrical arrangement and reverse currents of the magnetic sensing elements in the multiple magnetic sensing element pairs, the magnetic sensor according to the present disclosure can eliminate asymmetry of electric resistance of a single magnetic sensing element due to process deviation, and enable the magnetic sensor to sense the magnetic field intensity more accurately.

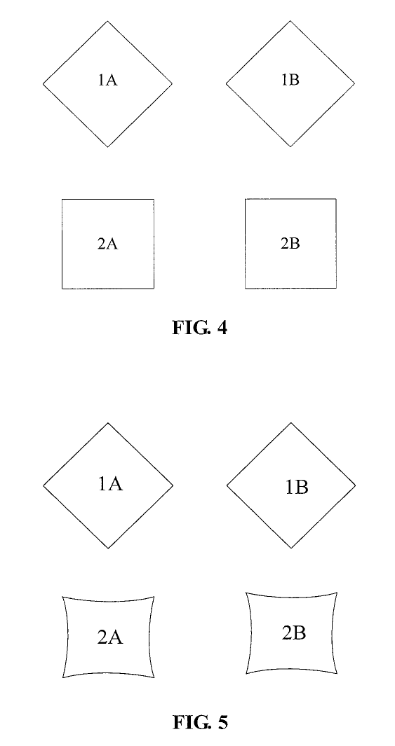

FIG. 3 shows a schematic view of a magnetic sensor according to another embodiment. A magnetic sensor 20 is provided according to the present application, which includes multiple magnetic sensing elements 20a, 20b, 20c, and 20d. The multiple magnetic sensing elements 20a, 20b, 20c, and 20d are respectively arranged at four diagonal positions of a square semiconductor substrate. In this embodiment, the semiconductor substrate is a P-type substrate. Specifically, the magnetic sensing elements 20a and 20c are obliquely arranged at a certain angle, and the oblique angles of the magnetic sensing elements 20a and 20c are the same. The magnetic sensing elements 20a, 20b, 20c, and 20d form two magnetic sensing element pairs, in which currents in the magnetic sensing elements in each of the at least one magnetic sensing element pair are reverse and the magnetic sensing elements are arranged symmetrically.

In the embodiment, the magnetic sensing elements 20a and 20c diagonally arranged form a magnetic sensing element pair, and the magnetic sensing elements 20b and 20d diagonally arranged form the other magnetic sensing element pair. Each of the multiple magnetic sensing elements includes four contact terminals. Specifically, for each of the magnetic sensing element, each contact terminal of the magnetic sensing element is connected with a corresponding contact terminal bus, thus forming bus contact terminals W, E, S, and N. In the embodiment, each of the multiple magnetic sensing elements is in a cross shape, and the four contact terminals are respectively arranged on four endpoints of the magnetic sensing element, as shown in FIG. 3. The magnetic sensing elements 20a and 20c according to this embodiment may be obliquely arranged, and the magnetic sensing elements 20b and 20d according to the embodiment may also be arranged similarly as the magnetic sensing elements 20a and 20c, as long as that the magnetic sensing elements 20a, 20b, 20c, and 20d can form two magnetic sensing element pairs and currents in the magnetic sensing elements in each of the two magnetic sensing element pairs are reverse and the magnetic sensing elements are arranged symmetrically are ensured.

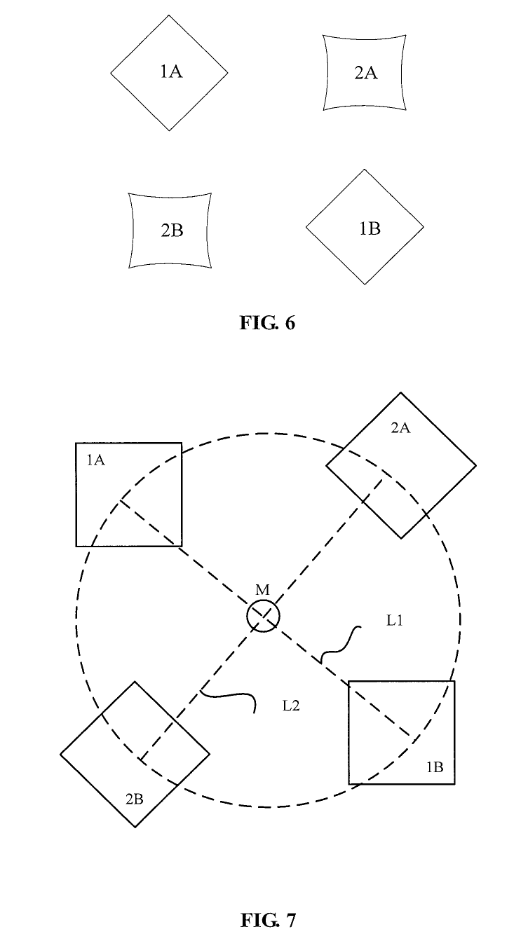

FIG. 4 shows that two magnetic sensing elements arranged side by side form a magnetic sensing element pair, and the magnetic sensing element of the two magnetic sensing element pairs have the same geometrical shape, and the magnetic sensing elements of the two pairs of magnetic sensing elements may be arranged in different positions, as long as the magnetic sensing elements of each of the two pairs of magnetic sensing elements are symmetrical and currents in the magnetic sensing elements reverse currents are reverse.

FIG. 5 shows that the two magnetic sensing elements arranged side by side form a magnetic sensing element pair, and the two pairs of magnetic sensing elements have different geometrical shapes.

FIG. 6 shows that two magnetic sensing elements diagonally arranged form magnetic sensing element pairs, and the two pairs of magnetic sensing elements have different geometrical shapes.

In the above embodiments, the magnetic sensing elements corresponding to one magnetic element pair may have a same geometrical shape, and the magnetic sensing elements corresponding to different magnetic sensing element pairs may have different geometrical shapes, which may not be consistent with the geometrical shape of the magnetic sensing elements corresponding to other magnetic sensing element pairs, however, the magnetic sensing elements corresponding to each magnetic sensing element pair must be in a same geometrical shape, and are not necessary to be diagonally symmetric as shown in FIGS. 2 and 3, specifically, as shown in FIGS. 4 to 6.

The geometrical arrangement of the multiple magnetic sensing element pairs is in a diamond shape or square shape, as specifically shown in the schematic views of FIGS. 2 to 6. The magnetic sensor includes four magnetic sensing elements, and the four magnetic sensing elements are respectively arranged at four diagonal positions on a square semiconductor substrate, and the magnetic sensing elements located at positions, diagonal to each other, of the square shape substrate respectively form one magnetic sensing element pair.

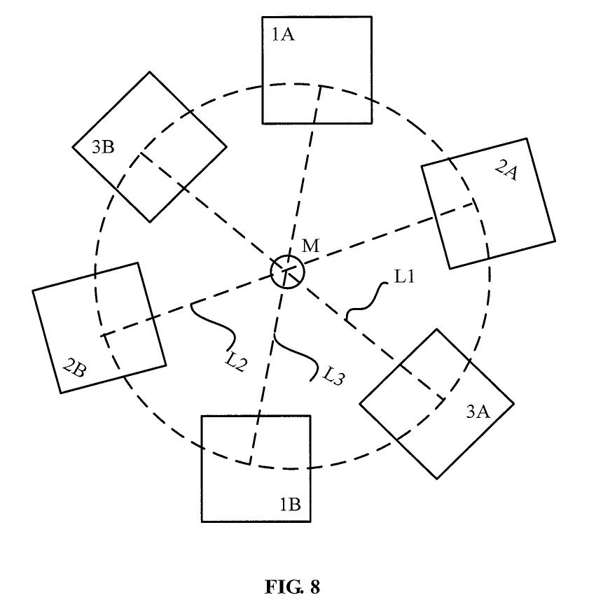

Preferably, the geometrical arrangement of the multiple magnetic sensing element pairs is an arrangement in which centers of the magnetic sensing elements are located on a same circle. Each of FIGS. 7 and 8 show a schematic view of a geometrical layout of a magnetic sensor. Specifically, another advantageous possible arrangement of the geometrical arrangement for the magnetic sensing element pairs is to locate centers of the magnetic sensing elements on a circle. Taking the geometrical arrangement of two pairs of magnetic sensor elements 1A, 1B and 2A and 2B as an example, as shown in FIG. 7, connecting lines L1 and L2 each represent a schematic connection between geometrical centers of two magnetic sensing elements of a magnetic sensor element pair. Connecting lines L1 and L2 of two pairs of magnetic sensing elements 1A, 1B and 2A and 2B intersect at point M, which represents a geometrical center of the whole magnetic sensor.

FIG. 8 shows an example of geometrical arrangement of three pairs of magnetic sensing elements. Connecting lines L1, L2 and L3 each represent a schematic connection between geometrical centers of the two magnetic sensing elements of a magnetic sensing element pair. Connecting lines L1, L2 and L3 of three pairs of magnetic sensing elements 1A and 1B, 2A and 2B, and, 3A and 3B intersect at point M, which represents a geometrical center of the whole magnetic sensor.

In summary, a magnetic sensor is provided according to the present application, which includes multiple magnetic sensing elements forming at least one magnetic sensing element pair. Two magnetic sensing elements in each of the at least one magnetic sensing element pair have reverse currents and are arranged symmetrically. By the symmetrical arrangement and reverse currents of the magnetic sensing elements in the multiple magnetic sensing element pairs, the magnetic sensor according to the present application eliminates asymmetry of electric resistance of a single magnetic sensing element of a conventional magnetic sensor due to process deviation, and enables the magnetic sensing elements to sense the magnetic field intensity more accurately.

1. A magnetic sensor, comprising:
at least two magnetic sensing elements,
wherein the at least two magnetic sensing elements form at least one magnetic sensing element pair, and currents in the magnetic sensing elements are reverse and the magnetic sensing elements are arranged symmetrically in each of the at least one magnetic sensing element pair.

2. The magnetic sensor according to claim 1, wherein each of the magnetic sensing elements comprises four contact terminals; and the contact terminals of each of the magnetic sensing elements are in connection with corresponding contact terminal buses respectively to form bus contact terminals.

3. The magnetic sensor according to claim 2, wherein each of the magnetic sensing elements is in a cross shape, and the four contact terminals are respectively arranged at four endpoints of the magnetic sensing element.

4. The magnetic sensor according to claim 2, wherein the contact terminals of each of the magnetic sensing elements are connected to the corresponding contact terminal buses via connecting lines having a same length.

5. The magnetic sensor according to claim 1, wherein the magnetic sensing elements in the magnetic sensing element pair have a same geometrical shape.

6. The magnetic sensor according to claim 1, wherein the magnetic sensing elements in different magnetic sensing element pairs have different geometrical shapes.

7. The magnetic sensor according to claim 1, wherein a geometrical arrangement of the at least one magnetic sensing element pair is in a square shape, a diamond shape or a circular shape.

8. The magnetic sensor according to claim 1, comprising:
four magnetic sensing elements arranged in a square semiconductor substrate; wherein the magnetic sensing elements located at four diagonal positions of the square semiconductor substrate, and two diagonal magnetic sensing elements form a magnetic sensing element pair.

9. The magnetic sensor according to claim 8, wherein the two magnetic sensing elements arranged at diagonal positions are obliquely arranged at a same angle.

10. The magnetic sensor according to claim 1, wherein the at least one magnetic sensing elements are located on edges of a circle.

11. A magnetic sensor, comprising:
at least one magnetic sensing element pair, and each of the at least one magnetic sensing element pair comprising two magnetic sensing elements;
wherein currents in the two magnetic sensing element are reverse and the two magnetic sensing elements are arranged symmetrically in each of the at least one magnetic sensing element pair.

12. The magnetic sensor according to claim 11, wherein each of the two magnetic sensing elements comprises four contact terminals; and the contact terminals of each of the two magnetic sensing elements are in connection with corresponding contact terminal buses respectively to form bus contact terminals.

13. The magnetic sensor according to claim 12, wherein each of the two magnetic sensing elements is in a cross shape, and the four contact terminals are respectively arranged at four endpoints of the magnetic sensing element.

14. The magnetic sensor according to claim 12, wherein the contact terminals of each of the two magnetic sensing elements are connected to the corresponding contact terminal buses via connecting lines having a same length.

15. The magnetic sensor according to claim 11, wherein the two magnetic sensing elements in the magnetic sensing element pair have a same geometrical shape.

16. The magnetic sensor according to claim 11, wherein the two magnetic sensing elements in different magnetic sensing element pairs have different geometrical shapes.

17. The magnetic sensor according to claim 11, wherein a geometrical arrangement of the at least one magnetic sensing element pair is in a square shape, a diamond shape or a circular shape.

18. The magnetic sensor according to claim 11, comprising:
four magnetic sensing elements arranged in a square semiconductor substrate; wherein the magnetic sensing elements located at four diagonal positions of the square semiconductor substrate, and two diagonal magnetic sensing elements form a magnetic sensing element pair.

19. The magnetic sensor according to claim 18, wherein the two magnetic sensing elements arranged at diagonal positions are obliquely arranged at a same angle.

20. The magnetic sensor according to claim 11, wherein the at least one magnetic sensing elements are located on edges of a circle.
